(19) United States
(12) Patent Application Publication
(10) Pub. No.: US 2009/0121905 A1
(43) Pub. Date: May 14, 2009

(54) Cylindrical Remote Control

(76) Inventors: Paul P. Griffin, JR., Nashville, TN (US); Mark David Rowan, Franklin, TN (US)

Correspondence Address: HORNKOHL INTELLECTUAL PROPERTY LAW, P.L.L.C, P.O. BOX 210584, NASHVILLE, TN, 37221, US

(21) Appl. No.: 11/936,798

(22) Filed: Nov. 8, 2007

(51) Int. Cl. H03K 17/94

(52) U.S. Cl. 341/35

(57) ABSTRACT

A remote control for an electronic device has a cylindrical body that can be rotated to control a function of the device. An outer circumference of the cylindrical body can rotate or an orientation sensor can be used to detect rotation of the remote body itself. A mounting portion allows the remote to be securely mounted on a mounting surface. Transport controls for the device are positioned on an upper face of the cylindrical body. A radio frequency transmitter in the cylindrical body communicates control signals to the device or an accessory coupled to the device. The remote is powered by a rechargeable power supply that can be recharged by coupling the remote to a charger or docking the remote with a base station.

### CROSS-REFERENCES TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING OR COMPUTER PROGRAM LISTING APPENDIX

Not Applicable

### BACKGROUND OF THE INVENTION

Wireless remote controls for portable electronic devices are used to control the functions of the device from a distance. Typically, these devices use infrared radiation to communicate control signals to an infrared receiver in the device. As a result, these remotes must be pointed toward the infrared receiver in the receiving device in order to communicate control signals to the remote device. These remote controls are also typically square devices with keypads having numerous buttons and knobs positioned on a top surface thereof. These buttons are often small and difficult to manipulate without the user visually inspecting the remote. In addition, due to their ease of portability, traditional remotes are often misplaced or lost. Therefore what is needed is an improved remote control for an electronic device.

### BRIEF SUMMARY OF THE INVENTION

An embodiment of the present invention is directed toward a remote control for wirelessly controlling an electronic device that has a cylindrical body having a wireless transmitter and an outer circumferential portion. The wireless transmitter communicates controls signals from the remote control to the electronic device. The outer circumferential portion of the remote control rotates around the cylindrical body to control the device's volume. A magnetic or friction mounting portion is positioned on a lower face of the cylindrical body to prevent the center of the cylindrical body from rotating when the outer circumference is rotated. Additional user inputs are provided on an upper face of the cylindrical body.

Another embodiment of the present invention is directed toward an accessory for an electronic device. The accessory has a substantially cylindrical rotating control. The outer body of the cylindrical rotating control consists essentially of a cylindrical form. An upper face of the cylindrical rotating control has user inputs positioned thereon for controlling a function of the device. A radio frequency wireless transmitter communicates control signals from the cylindrical rotating control to the electronic device. A non-slip mounting portion is positioned on a lower face of the cylindrical rotating control. The wireless transmitter is positioned within the substantially cylindrical remote control. A base portion couples to the electronic device. The base portion receives the control signals from the wireless transmitter and couples the control signals to the electronic device. The base portion includes a charger for charging a power supply for the wireless transmitter when the base is electrically coupled to the power supply. The base station also includes an FM transmitter for transmitting music from the device to a remote receiver.

Yet another embodiment of the present invention is directed toward a remote control for an electronic device. The remote control includes a transmitter for transmitting control signals to the electronic device. The outer body of the remote control consists of a cylinder. A portion of the outer body rotates to control a function of the electronic device. The rotation can be sensed through any suitable means such as mechanical switch closures, a hall sensor detecting angular position, or a magnetic position sensor that detects a rotating magnetic field, or rotation relative to a fixed magnetic reference (i.e. magnetic north). A user input is positioned on an upper face of the outer body. A mounting portion is positioned on a lower face of the cylinder. The remote control has a rechargeable power supply and a microcontroller contained within the cylindrical body.

### BRIEF DESCRIPTION OF THE SEVERAL VIEWS OF THE DRAWINGS

FIG. 1A is an isometric view of a remote control constructed in accordance with an embodiment of the present invention;

FIG. 1B is a top view of a remote control constructed in accordance with an embodiment of the present invention;

FIG. 1C is a side view of a remote control constructed in accordance with an embodiment of the present invention;

FIG. 1D is a bottom view of a remote control constructed in accordance with an embodiment of the present invention;

FIG. 2 is a block diagram of a remote control constructed in accordance with an embodiment of the present invention;

FIG. 3 is an illustration of an embodiment of the present invention for use with a docking station; and

FIG. 4 is an illustration of an embodiment of the present invention for use in an automobile.

### DETAILED DESCRIPTION OF THE INVENTION

The present invention is directed toward a cylindrical remote control for an electronic device, or a remote control accessory for use with an electronic device, that has an outer circumference that rotates to function as a user control for a device function such as volume. A transmitter is positioned with the outer circumference that communicates controls signals to a remote receiver. Transport controls are positioned on an upper surface of the remote. The remote control has a non-slip pad on formed a lower surface that prevents the remote from sliding such that the remote can be mounted on a surface and function give the appearance of a volume knob positioned on the surface.

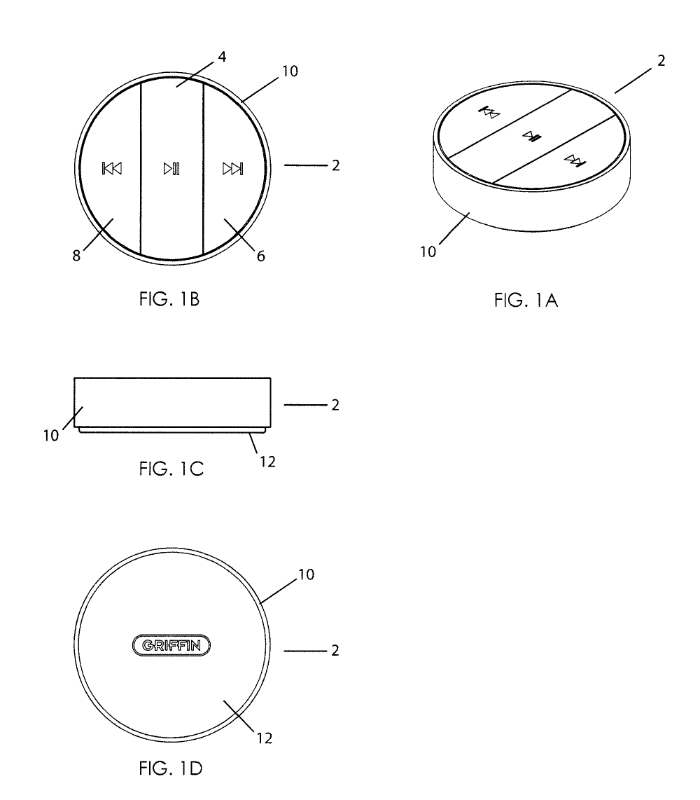

Referring now to FIG. 1, an illustration of a remote 2 constructed in accordance with an embodiment of the present invention is shown. The remote 2 is cylindrically shaped and has play/pause 4, forward 6 and reverse 8 user inputs on its upper surface. These controls 4, 6 and 8 are preferably used to control similar device functions on an electronic device such as a digital music player or DVD.

The outer circumference 10 of the remote 2 rotates around the center to control a device function, preferably the volume. Since it is the outer circumference of the remote 2 that controls the function, the user can simply feel for the remote and twist the circumferential control to alter the device function without the need to visually inspect the remote. The circular control is similar to the volume knob on many devices and allows for more precise control that typical up/down remote buttons and a better feel. In addition, the puck shaped remote has an aesthetic appearance when resting on a table that makes it appear as if the table has a volume knob on it.

The bottom of the cylindrical remote 2 has a mounting portion 12 that holds the remote control on a mounting surface. The mounting portion 12 is preferably a non-slip pad that prevents the remote control 2 from sliding across a smooth table surface. The mounting portion 12 can also be a magnet that removably attaches the remote control 2 to a ferromagnetic metal surface. Alternatively, the mounting portion 12 can have an adhesive surface that allows the remote to be stuck to a substantially flat surface. The center of the cylindrical remote should be prevented from sliding on the mounting surface such that the outer circumference 10 can be rotated without rotating the inner portion of the remote. This allows the controls 4, 6 and 8 to maintain their same position when the outer circumference 10 is rotated so that they can be easily located by a user.

In an alternative embodiment, an accelerometer can be positioned within the cylindrical remote 2 to sense when the cylindrical body itself is rotated. A magnetic sensor can also serve to detect rotation of the cylindrical body itself. While such an embodiment overcomes the need to prevent the center from rotating, the upper controls 4, 6 and 8 will also be rotated and will be more difficult for a user to accurately locate without visually inspecting the remote body.

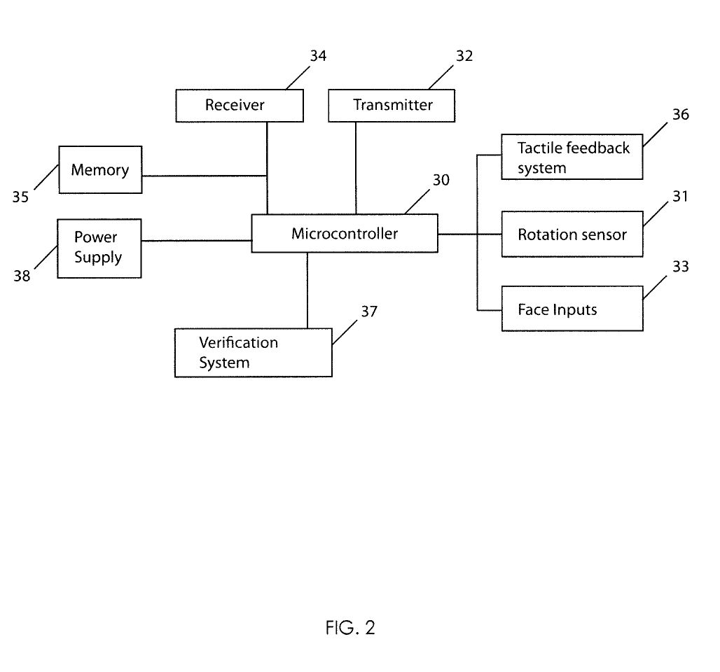

Referring now to FIG. 2, a block diagram of a remote control constructed in accordance with an embodiment of the present invention is shown. The functions of the remote control are controlled by a microprocessor 30. The microprocessor 30 receives signals from a rotational sensor 31 that detects manipulation of the circumferential portion of the remote. The rotational sensor 31 can be any suitable type of sensor such as a capacitive, resistive, magnetic or orientation sensor, an accelerometer, or a rotary encoder. The microprocessor 30 receives also inputs signals from the face inputs 33 of the remote control and interprets the signals into control signals codes that are communicated to the remote device though the transmitter 32.

The transmitter 32 allows the remote control to communicate control signals derived from the user inputs 31 and 33 to the electronic device. The transmitter is preferably a radio frequency transmitter such that line of sight contact does not have to be established between the remote control and the receiving device. However, an infrared transmitter could be used if desired. The remote's transmission format will depend upon the reception capabilities, such as wi-fi, Bluetooth, etc., of the device which it is designed to work.

The remote control can be equipped with a receiver 34 that can receive configuration data from a remote transmitter coupled to a computer. The receiver, like the transmitter, can be infrared, RF, wi-fi, Bluetooth, etc. depending upon the desired features and remote cost. By wireless coupling the remote control to a computer, the remote can be configured to work with a user's particular device through a software interface on the computer. In addition, the software interface can be used to repurpose controls of the remote to control alternative device functions specified by the user if desired. For example, the rotating circumferential portion can be repurposed between controlling volume and performing a back, forward, play function by altering the control signals produced by the microcontroller 30 in response to the signals received from the rotation sensor 31. The different functions can be selected through the software interface or buttons positioned on the upper or lower faces of the cylindrical remote control.

The remote can preferably be configured to manipulate menus displayed on a screen of the portable music player so that the user can make music and video selections with the remote control based upon menu selections displayed on the device's screen.

The remote control can be provided with a tactile feedback system 36 such that the circumferential portion resists or assists its rotation by a user. The microcontroller 30 retrieves the appropriate control information from the memory 35 and instructs the tactile feedback system 36 to provide the desired feedback.

The remote control may include a verification system 37 that cooperates with a verification system in the device to verify that the remote is being used in connection with an approved electronic device or that the accessory remote is an approved accessory for the device. The verification system 37 can use an identification resistor, a digital certificate, validation code or any other type of identification system or circuitry to verify that the device and remote are produced by approved entities.

The remote can use an ordinary battery as a power supply 38 so that the battery can be replaced as needed. Alternatively, the remote can use a lithium ion rechargeable power supply 38 that can be recharged through a barrel jack or similar input on the bottom face of the remote.

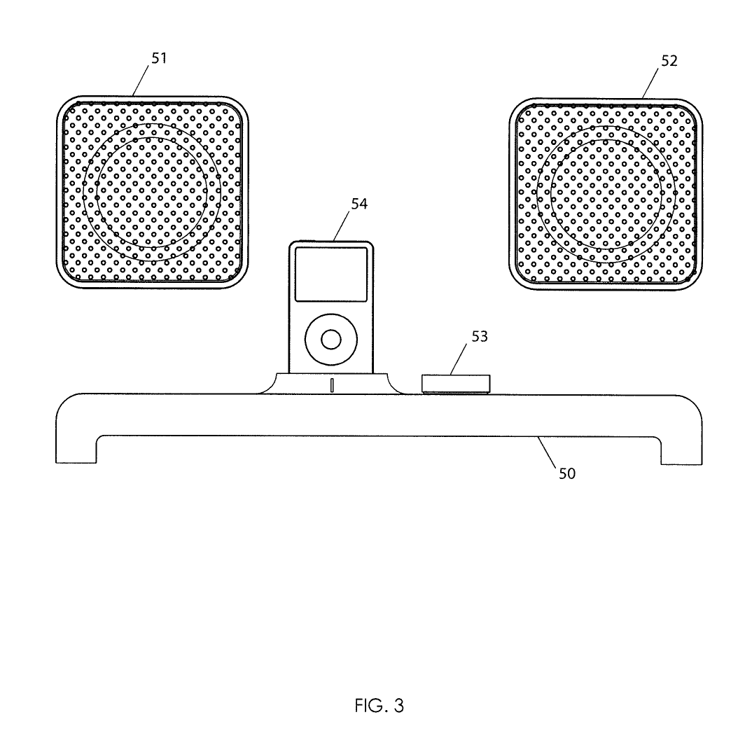

A remote control constructed in accordance with an embodiment of the present invention can also be configured to work with a set or wireless speakers connected to a dock for a digital music player as shown in FIG. 3. The base station 50 communicates wirelessly with the speakers 51 and 52 and the cylindrical remote 53. The base station 50 also couples to a digital music player 54 such that music from the player can be played over the speakers and the playing of the music controlled by the remote 53. The remote 53 and the removable speakers 51 and 52 can be removed from the base station 50 and positioned wherever the user desires as long as the remote and speakers are able to establish wireless communications with the base station. The base station 50 charges the speakers 51 and 52, remote 53 and portable electronic device 54 when they are docked to the station.

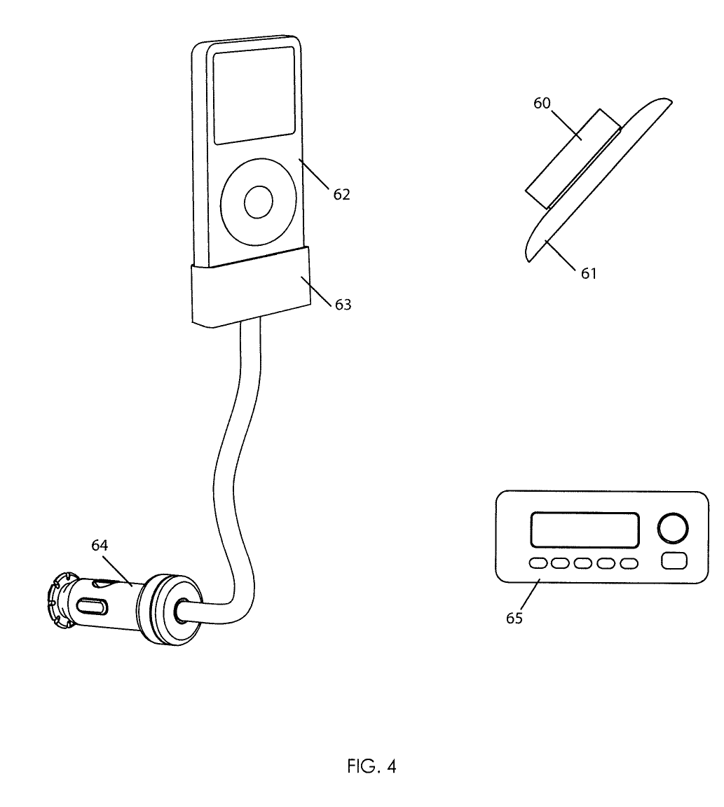

A remote constructed in accordance with an embodiment of the present invention is also particularly well adapted to use in an automobile. Such an embodiment is shown in FIG. 4. The remote 60 can be mounted on the dash or steering wheel 61 of the automobile to control the functions of a digital music player 62 mounted in a base station 63. In such an embodiment, the remote 60 transmits the appropriate signals to the base station 63 to instruct the base station to control the digital music player 62 that is coupled to the base station. The base station is preferably has a 12-volt car adapter 64 that receives power from the car outlet and charges the player 62. The remote 60 can either be recharged from the base station 63 or powered by a replaceable battery. The base station 63 contains an FM transmitter that transmits an FM signal to the car radio 65 based upon music being played by the digital music player 62. The base station 63 communicates wirelessly with the cylindrical control 60 which is mounted on the dash of the car. The remote 60 controls the functions of the digital music player 62 through the base station 63. The base station preferably charges the player when it is coupled to the player. By being positioned where it is most easily accessed and allowing the user to manipulate its controls primarily by touch, the present invention helps a user control their digital music player while maintaining their eyes on the road. The remote 60 can also be configured to transmit digital music contained in an internal memory directly to the car radio 65.

Although there have been described particular embodiments of the present invention of new and useful CYLINDRICAL REMOTE CONTROL, it is not intended that such references be construed as limitations upon the scope of this invention except as set forth in the following claims.

What is claimed is:

1. A remote control for wirelessly controlling an electronic device, said remote control comprising:
a cylindrical body having a wireless transmitter and an outer circumferential portion wherein said outer circumferential portion rotates around said cylindrical body to control a device function.

2. The remote control of claim 1 wherein said wireless transmitter further comprises a radio frequency transmitter.

3. The remote control of claim 1 wherein said cylindrical body communicates with a base station that is transmitting audio to a remote receiver.

4. The remote control of claim 3 wherein said base station further comprising a 12 volt car outlet adapter.

5. The remote control of claim 1 further comprising user inputs on an upper face of said cylindrical body.

6. The remote control of claim 1 further comprising a magnetic or friction mounting portion positioned on a lower face of said cylindrical body.

7. The remote control of claim 1 wherein said outer circumferential portion controls a control variable of said electronic device by sending relative increase/decrease value commands in response to rotation.

8. The remote control of claim 1 wherein said outer circumferential portion controls a device variable of said electronic device by sending a signal that indicates an absolute value for said variable to said device.

9. An accessory for an electronic device, said accessory comprising:
a substantially cylindrical rotating control wherein an upper face of said rotating control has user inputs positioned thereon for controlling a function of said device; and
a wireless transmitter for communicating control signals to said electronic device wherein said wireless transmitter is positioned within said substantially cylindrical remote control.

10. The accessory of claim 8 further comprising a base portion for coupling to said electronic device wherein said base portion receives said control signals from said wireless transmitter and couples said control signals to said electronic device.

11. The accessory of claim 10 wherein said base includes a charger for charging a power supply for said wireless transmitter when said base is electrically coupled to said power supply.

12. The accessory of claim 9 further comprising a non-slip mounting portion positioned on a lower face of said cylindrical rotating control.

13. The accessory of claim 9 wherein said wireless transmitter further comprises a radio frequency transmitter.

14. The accessory of claim 10 wherein said base station further comprises an FM transmitter for transmitting music from said device to a remote receiver.

15. The accessory of claim 9 wherein an outer body of said accessory consist essentially of a cylindrical form.

16. A remote control for an electronic device; said remote control comprising:
a transmitter for transmitting control signals to said electronic device;
an outer body consisting of a cylinder wherein rotation of the remote controls a function of said device.

17. The remote control of claim 16 further comprising a user input positioned on an upper face of said outer body.

18. The remote control of claim 16 wherein said rotation is sensed by means of a magnetic orientation sensor.

19. The remote control of claim 16 further comprising a mounting portion on a lower face of said cylinder.

20. The remote control of claim 16 further comprising a rechargeable power supply.
